(19) United States
(12) Patent Application Publication
(10) Pub. No.: US 2006/0001077 A1
(43) Pub. Date: Jan. 5, 2006

(54) Split gate type flash memory device and method of manufacturing the same

(75) Inventors: Eui-youl Ryu, Yongin-si (KR); Chul-soon Kwon, Seoul (KR); Jin-woo Kim, Suwon-si (KR); Yong-hee Kim, Suwon-si (KR); Dai-geun Kim, Suwon-si (KR); Joo-chan Kim, Seoul (KR)

Correspondence Address: LEE & MORSE, P.C., 1101 WILSON BOULEVARD, SUITE 2000, ARLINGTON, VA, 22209, US

(73) Assignee: Samsung Electronics Co., Ltd.

(21) Appl. No.: 11/152,779

(22) Filed: Jun. 15, 2005

(30) Foreign Application Priority Data
Jun. 15, 2004 (KR) 04-44097

(51) Int. Cl. H01L 29/788; H01L 21/8238

(52) U.S. Cl. 257/315; 438/201; 438/211

(57) ABSTRACT

In a split gate type flash memory device, and a method of manufacturing the same, the device includes a memory cell array having a memory cell uniquely determined by a contact of a corresponding bit line and a corresponding word line, a floating gate formed on a semiconductor substrate to constitute the memory cell, the floating gate having a horizontal surface parallel to a main surface of the substrate, a vertical surface perpendicular to the main surface of the substrate, and a curved surface extending between the horizontal and vertical surfaces, a control gate formed over the curved surface of the floating gate in an area defined by an angle range of less than 90° between an extension line of the horizontal surface and an extension line of the vertical surface, and source and drain regions formed in an active region of the substrate.

### BACKGROUND OF THE INVENTION

1. Field of the Invention

The present invention relates to a semiconductor memory device and a method of manufacturing the same. More particularly, the present invention relates to a split gate type flash memory device and a method of manufacturing the same.

2. Description of the Related Art

Recently, demand has increased for an Electrically Erasable and Programmable ROM (EEPROM) or a flash memory for performing electrical input and output of data. A flash memory device has various fields of application since data is able to be erased and stored, and data can be preserved, even when power is not supplied.

In a nonvolatile semiconductor memory device, memory cells are parallel-connected to a bit line such that a threshold voltage of a memory cell transistor is reduced to be less than a voltage (generally zero (0) V) applied to a control gate of a non-selection memory cell. In this arrangement, current flows between a source region and a drain region, irrespective of turn-on and turn-off of a selection memory cell, which causes all memory cells to perform an erroneous operation of on-state reading. Accordingly, the nonvolatile memory device has difficulty in strictly controlling the threshold voltage. Further, generating sufficient channel hot carriers for fast programming requires a high voltage. Furthermore, generating sufficient Fowler-Nordheim (F-N) tunneling current for fast erasure requires a high voltage.

In order to solve the above drawbacks, conventional split gate type nonvolatile semiconductor memory devices have been proposed. Further, as semiconductor memory devices are increasingly integrated, various structures and manufacturing processes have been proposed to improve an alignment between structural elements, such as a source region, a drain region, a control gate and a floating gate.

Recently, as a market for a portable information device having an image and voice processing and communicating function has expanded, an electronic equipment and an information terminal are required to satisfy requirements of lightweight, miniature size, and low cost, and an electronic device is required to satisfy requirements of low power consumption without a reduction in operation speed. Accordingly, a system on chip processor has been constructed to combine in one semiconductor chip a plurality of circuit systems having different functions, such as flash memory, logic circuit, Central Processing Unit (CPU), Integrated Circuit (IC) for processing image and voice data, and IC for communication, thereby providing many advantages to multimedia electronic equipment. In order to embody an embedded flash memory device having a concept of the system on chip processor, it is required to embody a reduced size of a memory cell.

The split gate type flash memory device has a structure in which the floating gate and the control gate are separated from each other. The floating gate has a structure of being entirely insulated and isolated from an exterior. In operation, information is stored using a current variation of the memory cell depending on electron injection (programming) into and electron emission (erasing) from the floating gate. The electron injection into the floating gate is performed by the Channel Hot Electron Injection (CHEI) method using hot carriers of a channel region. The electron emission uses F-N tunneling through an insulating film between the floating gate and the control gate.

In a conventional method of manufacturing a floating gate type flash memory device, a photolithography process is used to form the floating gate and the control gate. In order to compensate for misalignment of the photolithography process, a misalignment margin must be considered at the time of process design. However, the conventional method of manufacturing the flash memory device has a limit when a minute cell size suitable to the embedded flash memory device is embodied. Further, it has difficulty in ensuring a margin to embody the minute cell size due to a limit of resolution of the photolithography process.

### SUMMARY OF THE INVENTION

The present invention is therefore directed to a split gate type flash memory device and a method of manufacturing the same, which substantially overcome one or more of the problems due to the limitations and disadvantages of the related art.

It is a feature of an embodiment of the present invention to provide a flash memory device having a minute cell size that can be applied to an embedded flash memory cell.

It is another feature of an embodiment of the present invention to provide a method of manufacturing a flash memory device, in which a limit of resolution can be overcome in a photolithography process to assure a minute cell size, and a regular cell can be formed irrespective of a position on a wafer to ensure stability of the process.

At least one of the above and other features and advantages of the present invention may be realized by providing a split gate type flash memory device including a memory cell array having a memory cell uniquely determined by a contact of a corresponding bit line and a corresponding word line, a floating gate formed on a semiconductor substrate to constitute the memory cell, the floating gate having a horizontal surface parallel to a main surface of the semiconductor substrate, a vertical surface perpendicular to the main surface of the substrate, and a curved surface extending between the horizontal surface and the vertical surface, a control gate formed over the curved surface of the floating gate in an area defined by an angle range of less than 90° between an extension line of the horizontal surface of the floating gate and an extension line of the vertical surface of the floating gate, and source and drain regions formed in an active region of the substrate.

The control gate may have a horizontal surface parallel to the extension line of the horizontal surface of the floating gate.

The device may further include a floating gate insulating film formed between the horizontal surface of the control gate and the semiconductor substrate.

The device may further include a first insulating spacer formed on the source region to cover the vertical surface of the floating gate and a portion of the control gate concurrently, and a second insulating spacer formed on the drain region to cover a portion of the control gate adjacent to the horizontal surface of the control gate. The first insulating spacer may have a sidewall being in contact with the vertical surface of the floating gate and may extend vertically to the main surface of the semiconductor substrate. The first insulating spacer and the second insulating spacer may each be formed of one selected from the group including oxide, nitride or a combination thereof. The device may further include a metal silicide layer formed on the control gate between the first insulating spacer and the second insulating spacer.

The control gate may have a vertical surface parallel to the extension line of the vertical surface of the floating gate.

The device may further include a third insulating spacer having a sidewall positioned on the extension line of the vertical surface of the floating gate, and may be formed on the curved surface of the floating gate. The third insulating spacer may be formed of oxide. The device may further include an inter-gate insulating film formed on the curved surface of the control gate, and the control gate having a bottom surface facing the curved surface of the floating gate with the inter-gate insulating film interposed therebetween, wherein the bottom surface of the control gate has a length shorter than the curved surface of the floating gate.

At least one of the above and other features and advantages of the present invention may be realized by providing a method of manufacturing a split gate type flash memory device, the method including forming a gate insulating film on a semiconductor substrate, forming a mask pattern having a sidewall on the gate insulating film, forming a floating gate on the semiconductor substrate to be self-aligned to the sidewall of the mask pattern, forming an inter-gate insulating film on the floating gate, forming a control gate over the floating gate to be self-aligned to the sidewall of the mask pattern, and removing the mask pattern, and forming a source region and a drain region at a periphery of the floating gate and the control gate.

The mask pattern may be formed of silicon nitride.

The sidewall of the mask pattern may be perpendicular to a main surface of the semiconductor substrate.

Forming the floating gate may include forming a blanket conductive layer on the semiconductor substrate to cover the mask pattern, and etching-back the blanket conductive layer to form the floating gate covering a portion of the sidewall of the mask pattern.

Forming the control gate may include forming a blanket conductive layer on the semiconductor substrate to cover the mask pattern and the floating gate, and etching-back the blanket conductive layer to form the control gate covering a portion of the sidewall of the mask pattern and an upper surface of the floating gate.

The method may further include forming an insulating spacer on the floating gate to cover a portion of the sidewall of the mask pattern, before the forming of the control gate. The insulating spacer may be formed of oxide.

The method may further include forming a first insulating spacer on the source region to be in contact with the floating gate, and forming a second insulating spacer on the drain region to be in contact with the control gate. The method may further include forming a metal silicide layer on the source and drain regions, after forming the first insulating spacer and the second insulating spacer.

Since the floating gate and the control gate are formed to be self-aligned with the sidewall of the mask pattern using an etchback process, and not a photolithography process, a misalignment margin for compensating for misalignment caused by the photolithography process is not needed. Further, a limit of resolution can be overcome in the photolithography process to ensure a minute cell size. A regular cell can be formed irrespective of a position on a wafer to ensure stability of the process. Accordingly, a flash memory device with a minute cell size can be readily applied to the embedded flash memory cell.

### BRIEF DESCRIPTION OF THE DRAWINGS

The above and other features and advantages of the present invention will become more apparent to those of ordinary skill in the art by describing in detail exemplary embodiments thereof with reference to the attached drawings in which:

FIG. 1 illustrates a layout of a split gate type flash memory device according to embodiments of the present invention;

FIG. 2 illustrates a cross-sectional view of a memory cell (A) constituting a split gate type flash memory device according to a first embodiment of the present invention, and is a cross-sectional view taken along line II-II′ of FIG. 1;

FIG. 3 illustrates a cross-sectional view of a memory cell (A) constituting a split gate type flash memory device according to a second embodiment of the present invention, and is a cross-sectional view taken along line II-II′ of FIG. 1;

FIGS. 4A through 4I illustrate cross-sectional views of stages in a method of manufacturing a split gate type flash memory device according to a first embodiment of the present invention; and

FIGS. 5A through 5E illustrate cross-sectional views of stages in a method of manufacturing a split gate type flash memory device according to a second embodiment of the present invention.

### DETAILED DESCRIPTION OF THE INVENTION

Korean Patent Application No. 2004-44097, filed on Jun. 15, 2004, in the Korean Intellectual Property Office, and entitled: “Split Gate Type Flash Memory Device and Method of Manufacturing the Same,” is incorporated by reference herein in its entirety.

The present invention will now be described more fully hereinafter with reference to the accompanying drawings, in which exemplary embodiments of the invention are shown. The invention may, however, be embodied in different forms and should not be construed as limited to the embodiments set forth herein. Rather, these embodiments are provided so that this disclosure will be thorough and complete, and will fully convey the scope of the invention to those skilled in the art. In the figures, the dimensions of films, layers and regions are exaggerated for clarity of illustration. It will also be understood that when a layer is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

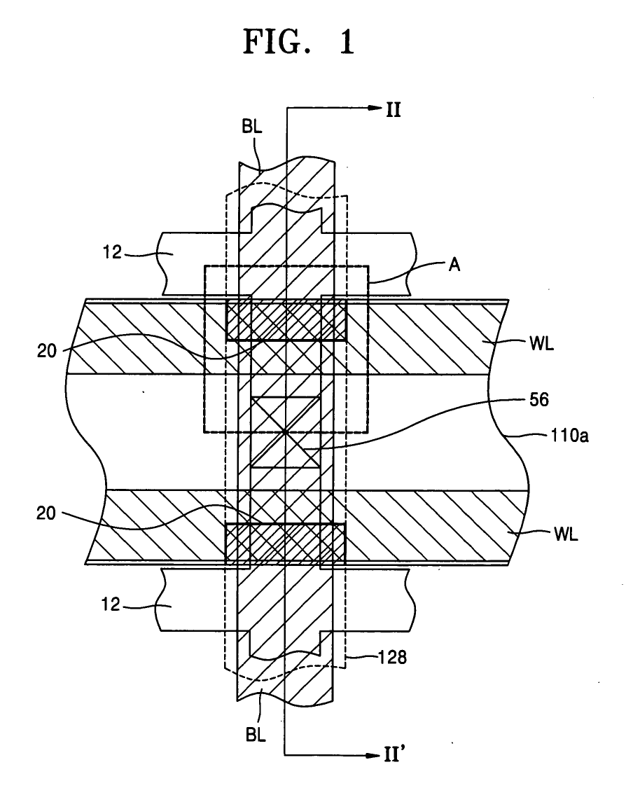

FIG. 1 illustrates a layout of a split gate type flash memory device according to embodiments of the present invention. FIG. 2 illustrates a cross-sectional view of a memory cell (A) constituting a split gate type flash memory device according to a first embodiment of the present invention, and is a cross-sectional view taken along line II-II′ of FIG. 1.

Referring to FIGS. 1 and 2, the split gate type flash memory device according to the first embodiment of the present invention includes a floating gate 20 formed on a gate insulating film 14 on a semiconductor substrate 10, in which an active region 12 is defined, and a word line (WL), i.e., a control gate 40, formed over the floating gate 20 with an inter-gate insulating film 32 interposed therebetween. A source region 52 and a drain region 54 are formed in the active region 12 of the semiconductor substrate 10. The word line (WL) constituting the control gate 40 extends orthogonally to a bit line (BL). One memory cell (A) is uniquely determined by a contact point of one bit line (BL) and one word line (WL). A plurality of memory cells (A) is arrayed in matrix form in a vertical direction and a horizontal direction at the intersections of a plurality of word lines (WL) and a plurality of bit lines (BL) on the semiconductor substrate 10. As shown in FIG. 1, two adjacent memory cells of the plurality of memory cells (A), which are arrayed in a direction in which the bit line (BL) extends, i.e., the bit line (BL) extension direction, share one drain region 54 and have a symmetric structure where a contact 56 of the drain region 54 and the bit line (BL) are interposed between two adjacent memory cells.

The floating gate 20 has a first surface 22, i.e., a horizontal surface, parallel to a main surface of the semiconductor substrate 10, a second surface 24, i.e., a vertical surface, perpendicular to the main surface of the semiconductor substrate 10, and a curved surface 26 extending between the horizontal surface 22 and the vertical surface 24.

The control gate 40 is formed over the curved surface 26 of the floating gate 20 in an area defined within an angle range of less than 90° between the horizontal surface 22 of the floating gate 20 extended, i.e., an extension line 22a of the horizontal surface 22 of the floating gate 20, and the vertical surface 24 of the floating gate 20 extended, i.e., an extension line 24a of the vertical surface 24 of the floating gate 20.

The control gate 40 has a third surface 42, i.e., a horizontal surface, parallel to the extension line 22a of the horizontal surface 22 of the floating gate 20, a fourth surface 44, i.e., a vertical surface, parallel to the extension line 24a of the second surface 24 of the floating gate 20, and a bottom surface 46, facing the curved surface 26 of the floating gate 20. A floating gate insulating film 16 is formed between the horizontal surface 42 of the control gate 40 and the semiconductor substrate 10.

A first insulating spacer 62 and a second insulating spacer 64 are respectively formed at both sides of the control gate 40. The first insulating spacer 62 is formed on the source region 52 to cover the vertical surface 24 of the floating gate 20 and the vertical surface 44 of the control gate 40. The first insulating spacer 62 has a vertical sidewall 62a in direct contact with the vertical surface 24 of the floating gate 20. The vertical sidewall 62a extends vertically to the main surface of the semiconductor substrate 10. The second insulating spacer 64 is formed on the drain region 54 to cover a portion of the control gate 40 adjacent to the horizontal surface 42 of the control gate 40. The first insulating spacer 62 and the second insulating spacer 64 may each be respectively formed of oxide, nitride or a combination thereof.

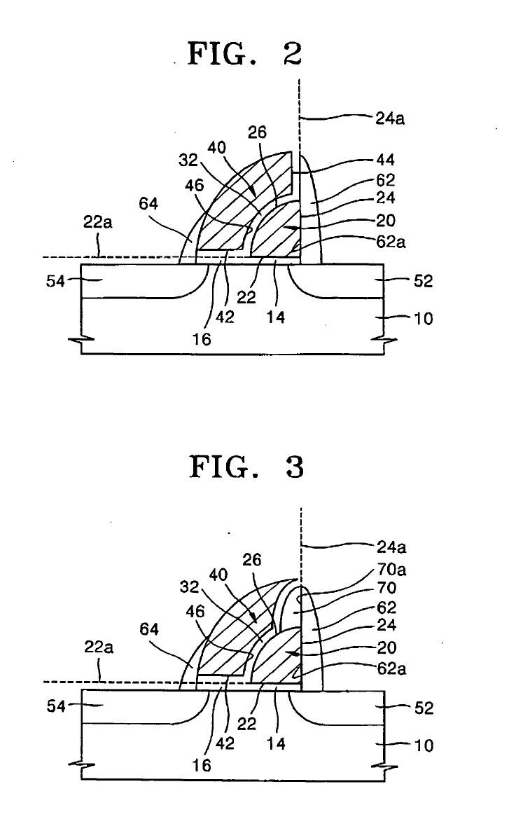

FIG. 3 illustrates a cross-sectional view of a memory cell (A) constituting a split gate type flash memory device according to a second embodiment of the present invention, and is a cross-sectional view taken along line II-II′ of FIG. 1. In FIG. 3, like reference numerals as in the first embodiment indicate like elements.

The second embodiment of FIG. 3 is substantially the same as the first embodiment, but differs from the first embodiment in that a third insulating spacer 70 is additionally formed on the curved surface 26 of the floating gate 20. The third insulating spacer 70 has a vertical sidewall 70a disposed on the extension line 24a of the second surface 24 of the floating gate 20. The third insulating spacer 70 may be formed of, e.g., oxide.

By forming the third insulating spacer 70, the bottom surface 46 of the control gate 40 has a shorter length than the curved surface 26 of the floating gate 20. The bottom surface 46 faces the curved surface 26 of the floating gate 20 with the inter-gate insulating film 32 interposed therebetween. More specifically, in the second embodiment, an overlap area of the floating gate 20 and the control gate 40 is reduced as compared to an overlap area in the first embodiment. Accordingly, a voltage applied to the control gate 40 has less affect on the floating gate 20 at the time of programming, to maximize a coupling caused by Channel Hot Electron Injection (CHEI).

Next, an operation of the split gate type flash memory device according to an embodiment of the present invention will be described.

First, programming is performed in a CHEI method using hot carriers in a channel region. In operation, a high voltage is applied to the word line (WL) of the memory cell, and a high voltage is applied to the source region 52 in an initial state. As a result, a channel region is formed by the threshold voltage (Vth) applied to the word line (WL), and electrons generated in the drain region 54 move to the source region 52 through the channel region. At this time, the channel hot carriers are generated such that hot electrons are injected into the floating gate 20 through the floating gate insulating film 16, and the floating gate 20 is negatively charged. After the programming, the floating gate 20 is charged by electrons, and a negative voltage is induced.

An erasure operation uses a F-N tunneling through the inter-gate insulating film 32 between the floating gate 20 and the control gate 40.

When data is erased, a high voltage is applied to the word line (WL) and a low voltage is applied to the source region 52. As a result, electrons stored in the floating gate 20 are tunneled to the word line (WL) by a strong electric field of a corner of the floating gate 20. If the electrons stored in the floating gate 20 all escape to the word line (WL) by the erasure operation, the floating gate 20 becomes in the initial state. At this time, the threshold voltage (Vth) of the channel region formed under the floating gate 20 is lower than the threshold voltage after the programming such that a relative high current flows at the time of reading.

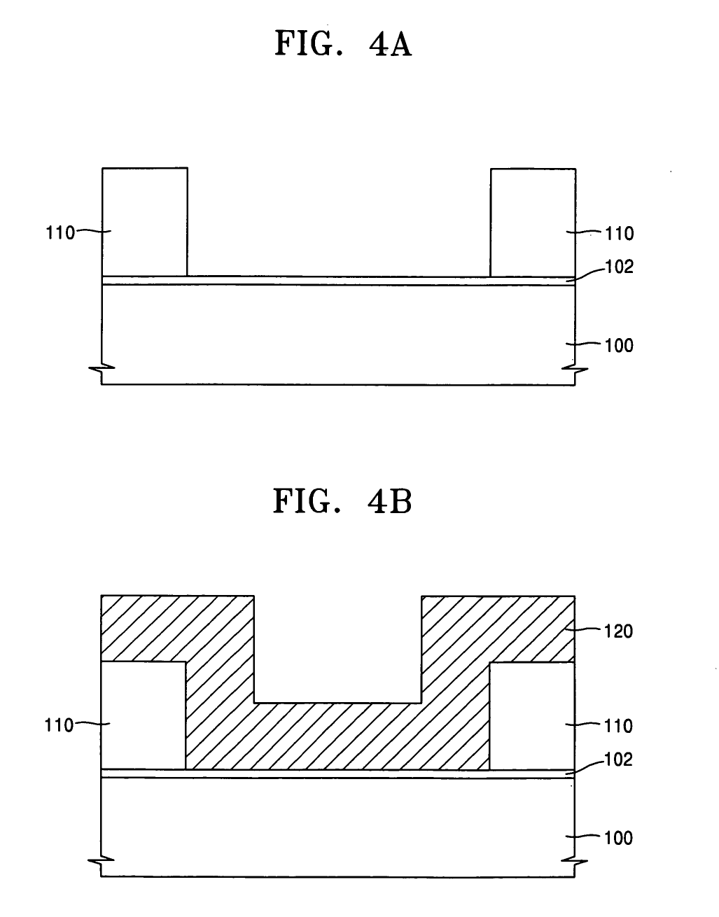

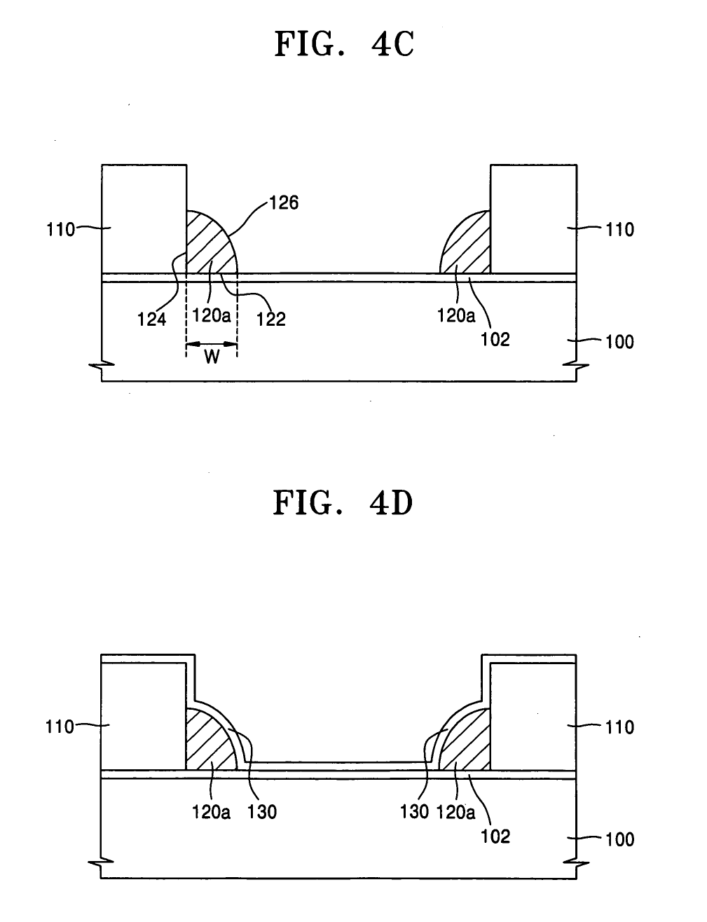

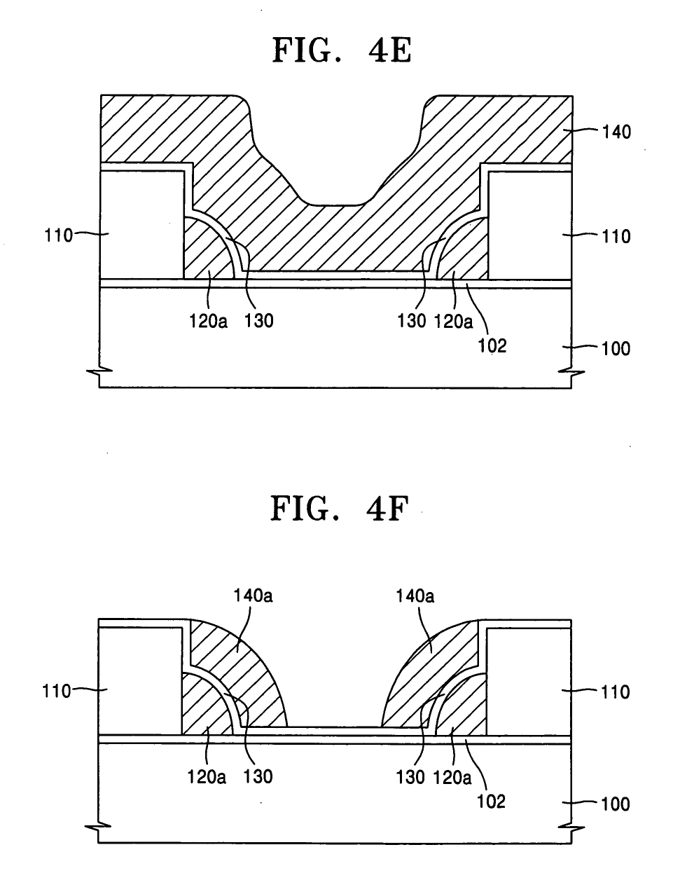

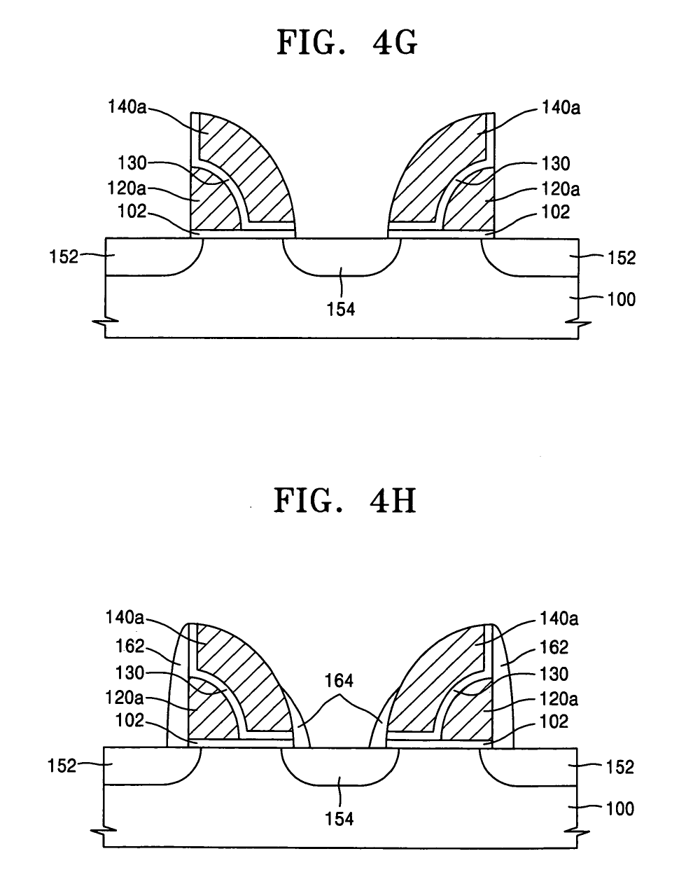

FIGS. 4A through 4I illustrate cross-sectional views of stages in a method of manufacturing a split gate type flash memory device according to the first embodiment of the present invention.

Referring to FIG. 4A, a gate insulating film 102 is formed on a semiconductor substrate 100 having an active region (12 of FIG. 1) defined through a device isolation process. A mask pattern 110 having a vertical sidewall perpendicular to a main surface of the semiconductor substrate 100 is formed on the gate insulating film 102. A thermal oxidation process, a chemical vapor deposition (CVD) process, or a combination thereof may be used to form the gate insulating film 102 to a thickness of about 80 Å. The mask pattern 110 may be formed of silicon nitride to have an opening pattern (110a of FIG. 1) therein. The mask pattern 110 may be formed to a thickness of, e.g., about 3000 Å.

Referring to FIG. 4B, a first blanket conductive layer 120 is formed on the semiconductor substrate 100 to cover the gate insulating film 102 and the mask pattern 110. The first blanket conductive layer 120 may be formed of doped polysilicon.

Referring to FIG. 4C, the first blanket conductive layer 120 is etched using an etchback process to form a spacer-type conductive layer at a sidewall of the mask pattern 110. Subsequently, the conductive layer is separated per cell unit in a direction in which the word line (WL of FIG. 1) extends, i.e., the word line (WL) extension direction, to form floating gate 120a. At this time, an amount etched during the etchback process may be controlled to form the floating gate 120a having a height about one-half of a height of the mask pattern 110. Further, as a width (W) of the floating gate 120a increases, an efficiency of programming is increased, and a distance between the source region and the drain region is increased to prevent a punch-through. In order to separate the spacer-type conductive layer per cell unit, the mask pattern is formed to have a shape, indicated by reference numeral 128 in FIG. 1, on the spacer-type conductive layer, and then the mask pattern is used as an etching mask to anisotropically etch the spacer-type conductive layer. As a result, the floating gate 120a (20 of FIG. 1) separated per cell unit is obtained. Since the floating gate 120a is self-aligned and formed at the vertical sidewall of the mask pattern 110, a separate alignment margin for forming the floating gate 120a in a memory cell region is not required.

The floating gate 120 has a first surface 122, i.e., a horizontal surface, parallel to the main surface of the semiconductor substrate 100, a second surface 124, i.e., a vertical surface, perpendicular to the main surface of the semiconductor substrate 100, and a curved surface 126 extending between the horizontal surface 122 and the vertical surface 124.

Referring to FIG. 4D, an inter-gate insulating film 130 is formed on the floating gate 120a. The inter-gate insulating film 130 may be formed to have a greater thickness than the gate insulating film 102. For example, the inter-gate insulating film 130 may be formed to a thickness of about 150 Å. The inter-gate insulating film 130 may be formed of, e.g., oxide, nitride or a combination thereof.

Referring to FIG. 4E, a second blanket conductive layer 140 is formed on the inter-gate insulating film 130. The second blanket conductive layer 140 may be formed of doped polysilicon.

Referring to FIG. 4F, after the second blanket conductive layer 140 is etched using the etchback process to form a spacer-type conductive layer at the vertical sidewall of the mask pattern 110, the conductive layer is patterned using a predetermined mask pattern to form a plurality of word lines (WL of FIG. 1). As a result, the word line (WL) is formed at the sidewall of the mask pattern 110 and over the floating gate 120a in a self-alignment method. A control gate 140a is formed by the word line (WL). Since the control gate 140a is formed using a self-alignment method at the vertical sidewall of the mask pattern 110, a separate alignment margin for forming the control gate 140a in the memory cell region is not required.

Referring to FIG. 4G, the mask pattern 110 and the insulating film remaining thereon are selectively removed to expose an upper surface of the semiconductor substrate 100 in the active region disposed at a periphery of the floating gate 120a and the control gate 140a. An implantation is then performed on the semiconductor substrate 100 to form a source region 150 and a drain region 154. Two adjacent memory cells of the bit line (BL) extension direction share one drain region 154.

Referring to FIG. 4H, an insulating material is deposited and etched-back over an entire surface of the resultant structure having the source region 152 and the drain region 154 to form a first insulating spacer 162 on the source region 152 and a second insulating spacer 164 on the drain region 154. The first insulating spacer 162 and the second insulating spacer 164 may each be respectively formed of oxide, nitride, or a combination thereof.

Referring to FIG. 4I, a general salicide process is used to form metal silicide layers 172, 174 and 176 on the source region 152, the drain region 154 and the control gate 140a, respectively. By forming the metal silicide layers 172, 174 and 176, a surface resistance and a contact resistance may be reduced at each contact. The metal silicide layers 172,174 and 176 may be formed of a cobalt silicide, a nickel silicide, a titanium silicide, a hafnium silicide, a platinum silicide, or a tungsten silicide, and may preferably be formed of the cobalt silicide.

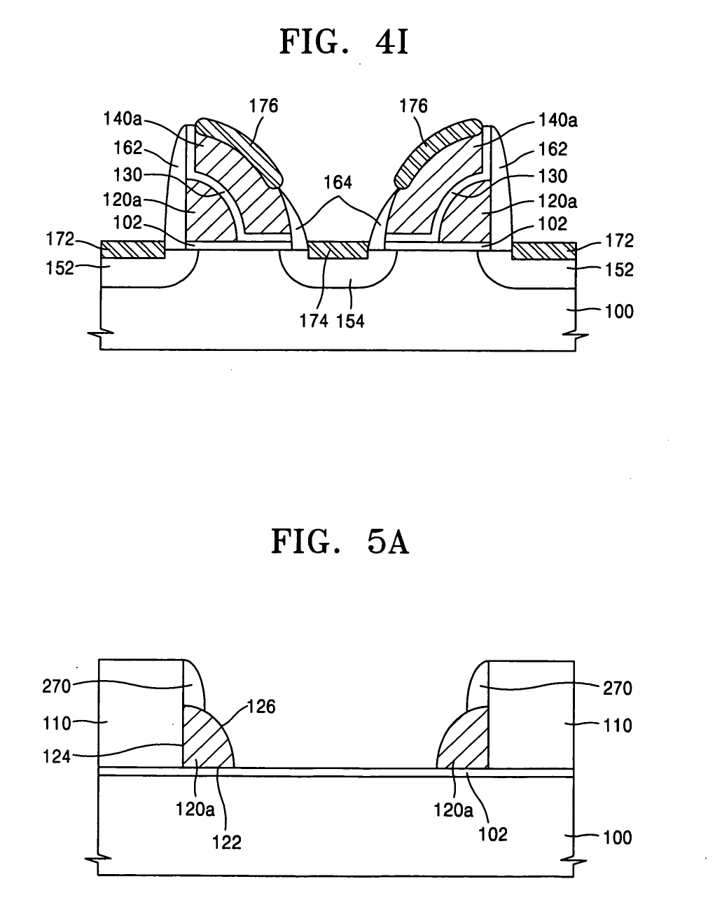

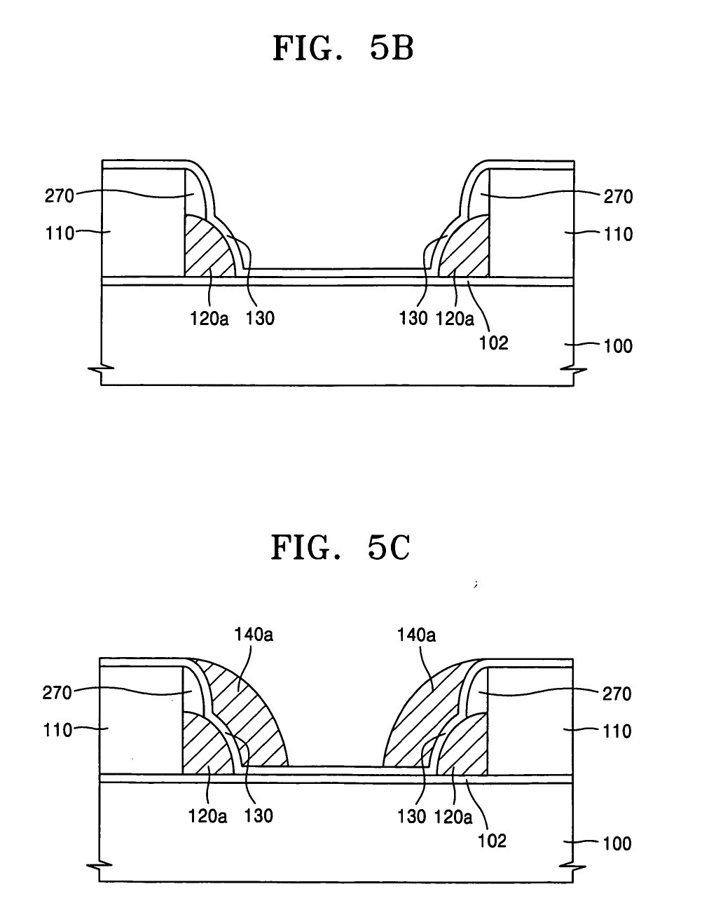

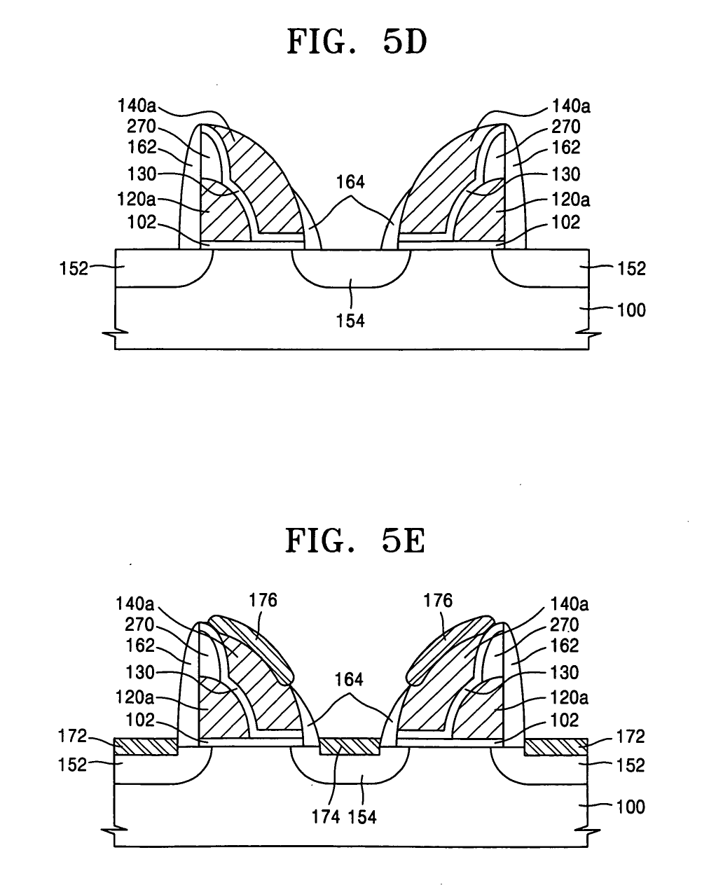

FIGS. 5A through 5E illustrate cross-sectional views of stages in a method of manufacturing a split gate type flash memory device according to a second embodiment of the present invention. The second embodiment is substantially the same as the first embodiment, but differs from the first embodiment in that a third insulating spacer 270, as previously described with reference to FIG. 3, is additionally formed on the curved surface 126 of the floating gate 120a.

In FIGS. 5A through 5E, like reference numerals as in the first embodiment described with reference to FIGS. 4A through 4I indicate like elements.

Referring to FIG. 5A, after the floating gate 120a is formed on the semiconductor substrate 100, as described with reference to FIGS. 4A through 4C, an insulating material, i.e., oxide, is deposited and etched-back over an entire surface of the resultant structure to form the third insulating spacer 270 on the vertical sidewall of the mask pattern 110 and on the curved surface 126 of the floating gate 120a.

Referring to FIG. 5B, the inter-gate insulating film 130 is formed on the floating gate 120a and the third insulating spacer 270, as described with reference to FIG. 4D.

Referring to FIG. 5C, the control gate 140a is formed at a sidewall of the third insulating spacer 270 and over the floating gate 120a in the self-alignment method, as described with reference to FIGS. 4E and 4F. By forming the third insulating spacer 270 over the floating gate 120a, an overlap area of the floating gate 120a and the control gate 140a with the inter-gate insulating film 130 interposed therebetween is reduced as compared to the first embodiment, as described with reference to FIG. 4F. Accordingly, a voltage applied to the control gate 140a may have less affect on the floating gate 120a at the time of programming, to maximize the coupling caused by Channel Hot Electron Injection (CHEI).

Referring to FIG. 5D, in the same method described with reference to FIGS. 4G and 4H, the mask pattern 110 and the insulating film remaining thereon are selectively removed and the source region 152 and the drain region 154 are formed in the semiconductor substrate 100. Subsequently, the first insulating spacer 162 and the second insulating spacer 164 are formed on the source region 152 and the drain region 154, respectively.

Referring to FIG. 5E, metal silicide layers 172, 174 and 176 are formed on the source region 152, the drain region 154 and the control gate 140a, respectively, using the same method as described with reference to FIG. 4I.

In a split gate type flash memory device according to an embodiment of the present invention, the mask pattern is formed on the semiconductor substrate before the formation of the floating gate and the control gate. The floating gate and the control gate are then sequentially formed to be self-aligned with a vertical sidewall of the mask pattern. The floating gate and the control gate are formed to be self-aligned with the vertical sidewall of the mask pattern through an etchback process, and not a photolithography process. Therefore, a misalignment margin for compensating for misalignment caused by the photolithography process is not needed. Further, a limit of resolution can be overcome in the photolithography process to ensure a minute cell size. A regular cell can be formed irrespective of a position on a wafer to ensure stability of process. Accordingly, a flash memory device with the minute cell size may be readily applied to the embedded flash memory cell.

Further, since the amount etched can be controlled at the time of the etchback process for forming the floating gate to control the width of the floating gate, the width of the floating gate may be readily increased to advantageously enhance an efficiency of programming and to prevent punch-through.

Exemplary embodiments of the present invention have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A split gate type flash memory device, comprising:
a memory cell array having a memory cell uniquely determined by a contact of a corresponding bit line and a corresponding word line;
a floating gate formed on a semiconductor substrate to constitute the memory cell, the floating gate having a horizontal surface parallel to a main surface of the semiconductor substrate, a vertical surface perpendicular to the main surface of the substrate, and a curved surface extending between the horizontal surface and the vertical surface;
a control gate formed over the curved surface of the floating gate in an area defined by an angle range of less than 900 between an extension line of the horizontal surface of the floating gate and an extension line of the vertical surface of the floating gate; and
source and drain regions formed in an active region of the substrate.

2. The device as claimed in claim 1, wherein the control gate has a horizontal surface parallel to the extension line of the horizontal surface of the floating gate.

3. The device as claimed in claim 2, further comprising a floating gate insulating film formed between the horizontal surface of the control gate and the semiconductor substrate.

4. The device as claimed in claim 2, further comprising:
a first insulating spacer formed on the source region to cover the vertical surface of the floating gate and a portion of the control gate concurrently; and
a second insulating spacer formed on the drain region to cover a portion of the control gate adjacent to the horizontal surface of the control gate.

5. The device as claimed in claim 4, wherein the first insulating spacer has a sidewall being in contact with the vertical surface of the floating gate and extends vertically to the main surface of the semiconductor substrate.

6. The device as claimed in claim 4, wherein the first insulating spacer and the second insulating spacer are each formed of one selected from the group consisting of oxide, nitride or a combination thereof.

7. The device as claimed in claim 4, further comprising a metal silicide layer formed on the control gate between the first insulating spacer and the second insulating spacer.

8. The device as claimed in claim 1, wherein the control gate has a vertical surface parallel to the extension line of the vertical surface of the floating gate.

9. The device as claimed in claim 1, further comprising a third insulating spacer having a sidewall positioned on the extension line of the vertical surface of the floating gate, and formed on the curved surface of the floating gate.

10. The device as claimed in claim 9, wherein the third insulating spacer is formed of oxide.

11. The device as claimed in claim 9, further comprising:
an inter-gate insulating film formed on the curved surface of the control gate; and
the control gate having a bottom surface facing the curved surface of the floating gate with the inter-gate insulating film interposed therebetween,
wherein the bottom surface of the control gate has a length shorter than the curved surface of the floating gate.

12. A method of manufacturing a split gate type flash memory device, the method comprising:
forming a gate insulating film on a semiconductor substrate;
forming a mask pattern having a sidewall on the gate insulating film;
forming a floating gate on the semiconductor substrate to be self-aligned to the sidewall of the mask pattern;
forming an inter-gate insulating film on the floating gate;
forming a control gate over the floating gate to be self-aligned to the sidewall of the mask pattern; and
removing the mask pattern, and forming a source region and a drain region at a periphery of the floating gate and the control gate.

13. The method as claimed in claim 12, wherein the mask pattern is formed of silicon nitride.

14. The method as claimed in claim 12, wherein the sidewall of the mask pattern is perpendicular to a main surface of the semiconductor substrate.

15. The method as claimed in claim 12, wherein forming the floating gate comprises:
forming a blanket conductive layer on the semiconductor substrate to cover the mask pattern; and
etching-back the blanket conductive layer to form the floating gate covering a portion of the sidewall of the mask pattern.

16. The method as claimed in claim 12, wherein forming the control gate comprises:
forming a blanket conductive layer on the semiconductor substrate to cover the mask pattern and the floating gate; and
etching-back the blanket conductive layer to form the control gate covering a portion of the sidewall of the mask pattern and an upper surface of the floating gate.

17. The method as claimed in claim 12, further comprising forming an insulating spacer on the floating gate to cover a portion of the sidewall of the mask pattern, before the forming of the control gate.

18. The method as claimed in claim 17, wherein the insulating spacer is formed of oxide.

19. The method as claimed in claim 12, further comprising:
forming a first insulating spacer on the source region to be in contact with the floating gate; and
forming a second insulating spacer on the drain region to be in contact with the control gate.

20. The method as claimed in claim 19, further comprising:
forming a metal silicide layer on the source and drain regions, after forming the first insulating spacer and the second insulating spacer.
